(19) United States
(12) Patent Application Publication
(10) Pub. No.: US 2024/0386937 A1
(43) Pub. Date: Nov. 21, 2024

(54) SWITCHED-CAPACITOR VOLTAGE CONVERTER WITH SELECTIVE DECOUPLING CAPACITANCE

(71) Applicant: Intel Corporation, Santa Clara, CA (US)

(72) Inventors: Su Hwan Kim, Portland, OR (US); Chi-Hsiang Huang, Seattle, WA (US); Harish K. Krishnamurthy, Beaverton, OR (US)

(21) Appl. No.: 18/318,659

(22) Filed: May 16, 2023

(51) Int. Cl. G11C 11/4074; H02M 1/00; H02M 3/07; H02M 3/158

(52) U.S. Cl. CPC G11C 11/4074; H02M 1/007; H02M 3/07; H02M 3/158

(57) ABSTRACT

Various embodiments herein provide a switched capacitor voltage converter with a subset of one or more phases that selectively provide a decoupling capacitance. The voltage converter may include multiple phases coupled in parallel between an input terminal and an output terminal. The individual phases may include a capacitor and a set of switches. A first subset of one or more of the phases may operate in a switching mode in which the respective set of switches open and close to generate an output voltage at the output terminal based on an input voltage at the input terminal. The voltage converter may further include a second subset of one or more phases that are selectively operable in the switching mode or in a decoupling mode. In the decoupling mode, the switches of the respective phase may maintain the capacitor coupled between the output terminal and ground. Other embodiments may be described and claimed.

### FIELD

Embodiments of the present disclosure relate generally to the technical field of electronic circuits, and more particularly to switched-capacitor voltage converters.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure. Unless otherwise indicated herein, the approaches described in this section are not prior art to the claims in the present disclosure and are not admitted to be prior art by inclusion in this section.

Switched-capacitor voltage converters typically include one or more capacitors that are switched in and out of being coupled between an input terminal and an output terminal to generate an output voltage at the output terminal based on an input voltage at the input terminal. During startup of the voltage converter, the initial voltage of the capacitor should be initialized before it enters steady-state switching operation, e.g., in order to avoid a voltage spike at the output. Typically, this initialization is provided by a dedicated capacitance at the output or by a separate voltage supply.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 illustrates a switched capacitor voltage converter in accordance with various embodiments.

FIG. 2A illustrates a switched capacitor voltage converter with a first phase in a switching mode and a second phase in a decoupling mode, in accordance with various embodiments.

FIG. 2B illustrates the switched capacitor voltage converter of FIG. 2A with the first and second phases in the switching mode, in accordance with various embodiments.

FIG. 2C illustrates a switched capacitor voltage converter with an output terminal coupled to a buck converter, in accordance with various embodiments.

FIG. 3 illustrates example waveforms of a first control signal and a second control signal for a switched capacitor voltage converter, in accordance with various embodiments.

FIG. 4 illustrates further example waveforms associated with a switched capacitor voltage converter, in accordance with various embodiments.

FIG. 5A illustrates an example switched capacitor voltage converter with four phases, in which one of the phases is in the decoupling mode and the other phases are in the switching mode, in accordance with various embodiments.

FIG. 5B illustrates the switched capacitor voltage converter of FIG. 5A with all of the phases in the switching mode, in accordance with various embodiments.

FIG. 6 illustrates an example of a switched capacitor voltage converter with pulse frequency modulation (PFM) operation, in accordance with various embodiments.

FIG. 7 illustrates an example system configured to employ the apparatuses and methods described herein, in accordance with various embodiments.

### DETAILED DESCRIPTION

Various embodiments herein provide a switched capacitor voltage converter with a subset of one or more phases that selectively provide a decoupling capacitance. The voltage converter may include multiple phases coupled in parallel between an input terminal and an output terminal. The individual phases may include a capacitor and a set of switches. A first subset of one or more of the phases may operate in a switching mode in which the respective set of switches open and close to generate an output voltage at the output terminal based on an input voltage at the input terminal. For example, the switches may alternately switch the capacitor of respective phase between a first state, in which the capacitor is coupled between the input terminal and the output terminal, and a second state, in which the capacitor is coupled between the output terminal and a ground terminal. The voltage converter may further include a second subset of one or more phases that are selectively operable in the switching mode or in a decoupling mode. In the decoupling mode, the switches of the respective phase may maintain the capacitor coupled between the output terminal and ground (e.g., in the second state). Accordingly, the one or more phases of the second subset may provide a decoupling capacitance at the output terminal when in the decoupling mode.

In some embodiments, the one or more phases of the second subset may operate in the decoupling mode during startup of the voltage converter, e.g. to provide a decoupling capacitance for the one or more phases of the first subset which are operating in the switching mode. The one or more phases of the second subset may thereafter transition from the decoupling mode to the switching mode, e.g., for normal operation of the voltage converter. Thus, the voltage converter may provide integrated initialization of the capacitor voltage during startup, while maintaining normal soft-charging operation after startup (e.g., without a capacitor coupled full-time between the output and ground). The voltage converter may not require a separate power supply or dedicated decoupling capacitance, thus providing efficient use of circuit area compared with other techniques.

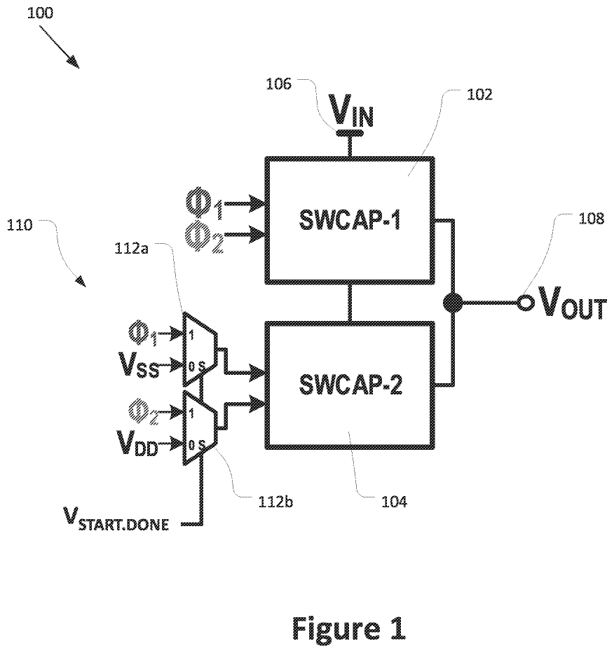

FIG. 1 illustrates an example voltage converter 100 in accordance with various embodiments. The voltage converter 100 includes a first phase 102 and a second phase 104. The first phase 102 and second phase 104 may be coupled between an input terminal 106 and an output terminal 108 to generate an output voltage (V_{OUT}) at the output terminal 108 based on an input voltage (V_{IN}) at the input terminal 106. For example, the first phase 102 and second phase 104 may be coupled in parallel with one another between the input terminal 106 and output terminal 108. In some embodiments, the output voltage may be less than the input voltage, e.g., a fraction of the input voltage.

Although the voltage converter 100 is shown with two phases, the voltage converter 100 may include any suitable number of two or more phases. In some embodiments, e.g. for a switching duty cycle of 50%, as further discussed below, the conversion ratio of the voltage converter 100 may depend on the number of phases. For example, a voltage converter 100 with a number, N, of phases, may generate an output voltage of V_{IN}/N. Accordingly, the voltage converter 100 shown in FIG. 1 may generate an output voltage of V_{IN}/2.

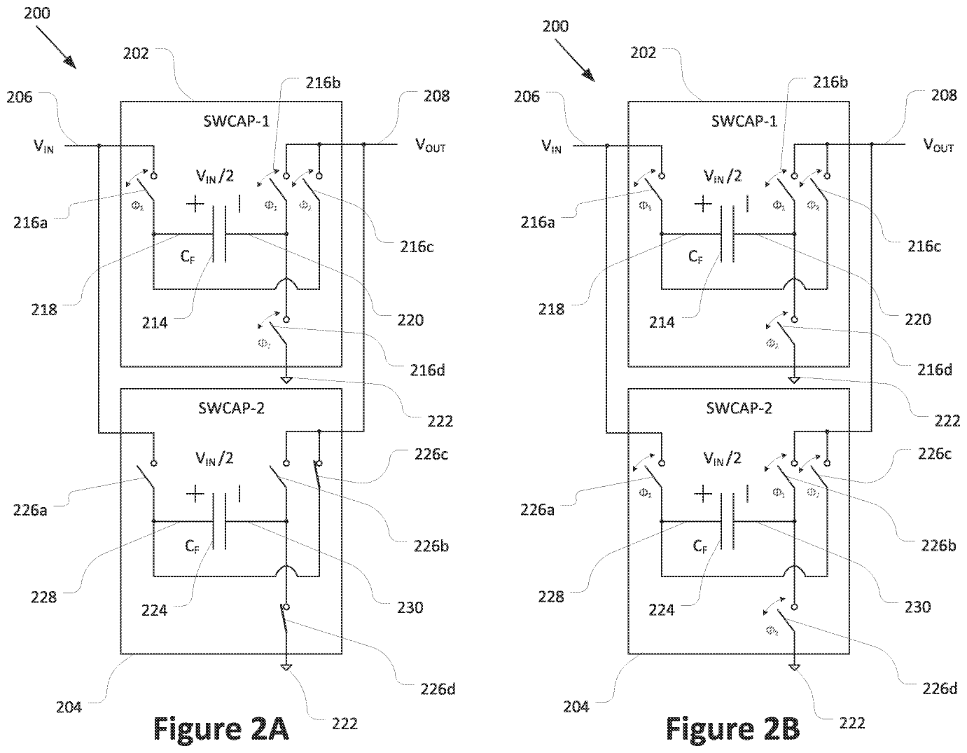

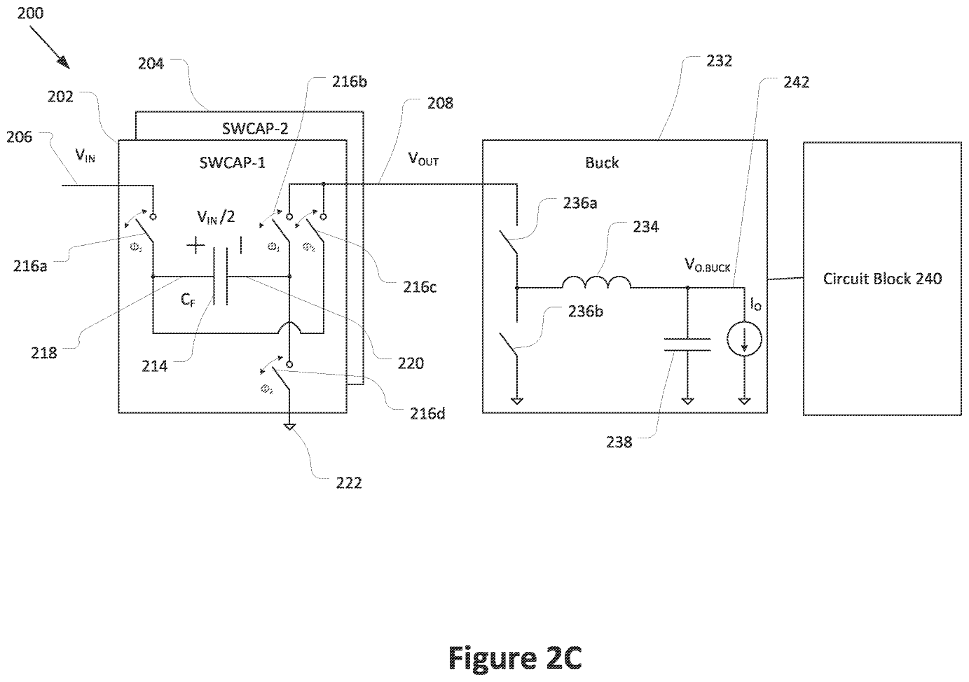

The first phase 102 and second phase 104 may each include a capacitor and one or more switches (e.g., as shown and described in voltage converter 200 of FIGS. 2A-2C, further discussed below). In various embodiments, the first phase 102 may operate in a switching mode based on a first control signal (Φ₁) and a second control signal (Φ₂). The second phase 104 may selectively operate in either the switching mode or a decoupling mode. The voltage converter 100 may include control circuitry 110 coupled to the second phase 104 to control the operating mode of the second phase 104. For example, the control circuitry 110 may include multiplexers 112a-b and/or other suitable circuitry. In the switching mode, the control circuitry 110 may pass the first and second control signals to the second phase. In the decoupling mode, the control circuitry 110 may instead pass a third control signal (e.g., V_{SS}) and a fourth control signal (e.g., V_{DD}) to the second phase 104 in place of the respective first and second control signals. The third and fourth control signals may maintain the capacitor of the second phase coupled between the output terminal 108 and ground.

In some embodiments, the second phase 104 may operate in the decoupling mode upon startup of the voltage converter 100. Accordingly, the second phase 104 may provide a capacitance at the output terminal 108 to initialize the voltage across the capacitor of the first phase 102. The first phase 102 may operate in the switching mode during startup of the voltage converter 100, while the second phase 104 is in the decoupling mode. The second phase 104 may thereafter transition to the switching mode for normal operation of the voltage converter 100. Accordingly, the first phase 102 and second phase 104 may both operate in the switching mode to generate the output voltage at the output terminal 108.

The operation of the voltage converter 100, including further details of the switching mode and decoupling mode, will be further described with respect to the example voltage converter 200 of FIGS. 2A-2C. The voltage converter 200 is merely one example implementation of the voltage converter 100, and other implementations may be used in accordance with various embodiments.

FIG. 2A illustrates the voltage converter 200 during startup, while FIG. 2B illustrates the voltage converter 200 in normal operation (e.g., after startup). The voltage converter 200 includes a first phase 202 and a second phase 204 coupled in parallel between an input terminal 206 and an output terminal 208. The first phase 202 includes a capacitor 214 and switches 216a-d. The capacitor 214 may have a first terminal 218 and a second terminal 220. The switch 216a may be coupled between the input terminal 206 and the first terminal 218 of the capacitor; the switch 216b may be coupled between the second terminal 220 of the capacitor 214 and the output terminal 208; the switch 216c may be coupled between the first terminal 218 of the capacitor 214 and the output terminal 208; and the switch 216d may be coupled between the second terminal 220 of the capacitor 214 and ground 222.

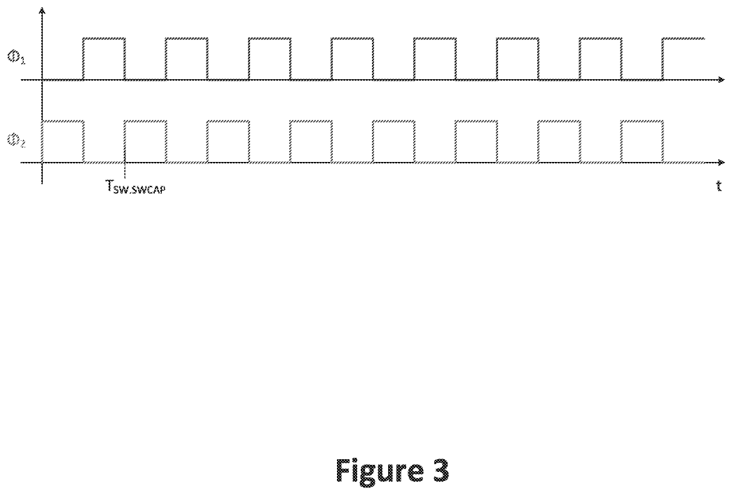

The first phase 202 may operate in the switching mode during both startup and normal operation of the voltage converter 200. The switches 216a and 216b may receive the first control signal (Φ₁) and the switches 216c and 216d may receive the second control signal (Φ₂). FIG. 3 illustrates example waveforms for the first and second control signals in accordance with some embodiments. The first and second control signals may both alternate between a first logic value (e.g., logic 0) and a second logic value (e.g., logic 1). The first control signal may have the first logic value when the second control signal has the second logic value, and may have the second logic value when the second control signal has the first logic value. In some embodiments, the first and second logic signals may have a duty cycle of 50%, as shown in FIG. 3. In other embodiments, a different and/or controllable duty cycle may be used. For example, some embodiments may use pulse width modulation (PWM) and/or pulse frequency modulation (PFM) control signals.

In the switching mode, the switches 216a-d may open and close responsive to the first and second switching signals to repeatedly switch the capacitor 214 between a first state and a second state. In the first state, the capacitor 214 may be coupled between the input terminal 206 and the output terminal 208 (e.g., with the first terminal 218 of the capacitor 214 coupled to the input terminal 206 and the second terminal 220 of the capacitor 214 coupled to the output terminal 208). In the second state, the capacitor 214 may be coupled between the output terminal 208 and ground 222 (e.g., with the first terminal 218 of the capacitor 214 coupled to the output terminal 208 and the second terminal 220 of the capacitor 214 coupled to ground 222).

The second phase 204 of the voltage converter 200 may include a capacitor 224 and switches 226a-d. The capacitor 224 may have a first terminal 228 and a second terminal 230. The capacitor 224 and switches 226a-d may be coupled in a similar configuration to capacitor 214 and switches 216a-d of the first phase 202. The second phase 204 may selectively operate in the switching mode or the decoupling mode. A control circuitry (e.g., control circuitry 110 of FIG. 1) may control the operating mode of the second phase 204. In the decoupling mode, as shown in FIG. 2A, the switches 226a and 226b may be maintained in an open state, and the switches 226c and 226d may be maintained in a closed state (e.g., responsive to respective control signals, such as the third and fourth control signals described with respect to control circuitry 110). Accordingly, the capacitor 224 may be coupled between the output terminal 208 and ground 222 (e.g., with the first terminal 228 of the capacitor 224 coupled to the output terminal 208 and the second terminal 230 of the capacitor 224 coupled to ground 222). Therefore, the second phase 204 may provide a capacitance at the output terminal 208 during the decoupling mode.

In the switching mode, as shown in FIG. 2B, the switches 226a and 226b of the second phase 204 may receive the first control signal (Φ₁) and the switches 226c and 226d may receive the second control signal (Φ₂). Accordingly, the second phase 204 may generate the output voltage at the output terminal 208 in parallel with the first phase 202.

In some embodiments, the second phase 204 may be in the decoupling mode during startup of the voltage converter 200, and may then transition from the decoupling mode to the switching mode for normal operation of the voltage converter 200. The second phase 204 may transition from the decoupling mode to the switching mode based on one or more triggers. For example, the second phase 204 may transition to the switching mode when the voltage across the capacitor 214 of the first phase 202 is above a threshold. In some embodiments, the threshold may be the target value of the output voltage (e.g., V_{IN}/2 for the voltage converter 200) or another suitable value. In other embodiments, another trigger may be used in addition to or instead of the voltage across the capacitor 214, such as expiration of a timer, a measurement of the output voltage, etc.

Accordingly, the voltage converter 200 may provide initialization of the voltage across the capacitor 214 for startup of the voltage converter 200 without requiring a dedicated output capacitance and/or a separate supply voltage. Therefore, the voltage converter 200 may increase area efficiency of the circuitry without performance degradation.

FIG. 2C illustrates an example implementation of the voltage converter 200, in which the output terminal 208 is coupled to a buck converter 232. In some embodiments, the buck converter 232 may include an inductor 234, switches 236a-b, and a capacitor 238, e.g., coupled as shown. A circuit block 240 may be coupled to the buck converter 232 (e.g., to an output terminal 242 of the buck converter 232) to receive a supply voltage from the buck converter 232. The buck converter 232 and/or circuit block 240 may be included in a same integrated circuit as the voltage converter 200, and/or in a separate integrated circuit.

The voltage converter 200 and/or buck converter 232 may be used to convert the input voltage provided by a power supply to a supply voltage that is used by the circuit block 240. For example, the power supply may be from a battery, a wall outlet (e.g., via an alternating current/direct current (AC/DC) adapter), a peripheral device (e.g., connected via universal serial bus (USB) and/or another suitable protocol), and/or an intermediate power supply that is input to and/or generated by an integrated circuit that includes the voltage converter 200.

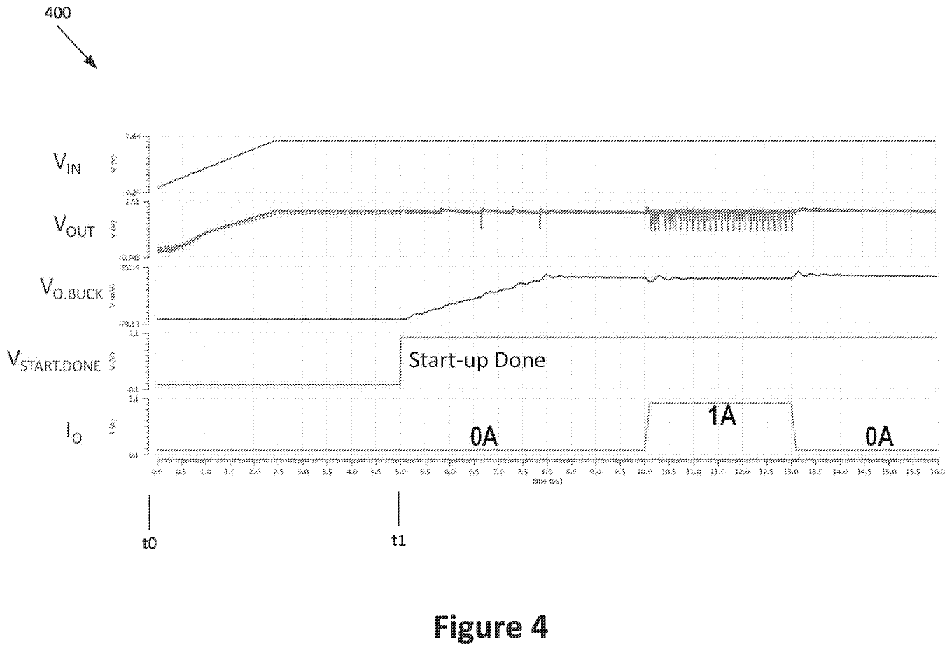

FIG. 4 illustrates example waveforms 400 associated with the voltage converter 200 and/or buck converter 232. The waveforms 400 include the input voltage (V_{IN}) at the input terminal 206 of the voltage converter 200, the output voltage (V_{OUT}) at the output terminal 208 of the voltage converter 200, the mode control signal (V_{START.DONE}) of the control circuitry (e.g., control circuitry 110), the output voltage (V_{O.BUCK}) at the output terminal 242 of the buck converter 232, and an output current (I_{O}) at the output terminal 242 of the buck converter.

As shown, startup of the voltage converter 200 begins at time t0. The input voltage begins to ramp up at startup. The mode control signal controls the second phase 204 of the voltage converter 200 to be in the decoupling mode, thereby providing a capacitance at the output terminal 208. The first phase 202 operates in the switching mode, which causes the output voltage to ramp up.

At time t1, the mode control signal changes logic value to transition the second phase 204 from the decoupling mode to the switching mode. Accordingly, the second phase 204 cooperates with the first phase 202 to generate the output voltage based on the input voltage. In some embodiments, the buck converter 232 may be activated at or after time t1, e.g., using switches 236a-b. Accordingly, the output voltage at the output terminal 242 of the buck converter 232 may ramp up. Thereafter, the circuit block 240 coupled to the output terminal 242 of the buck converter 232 may draw a current, thereby causing the output current of the buck converter 232 (I_{O}) to increase. The output voltage (V_{O.BUCK}) of the buck converter 232 may remain stable.

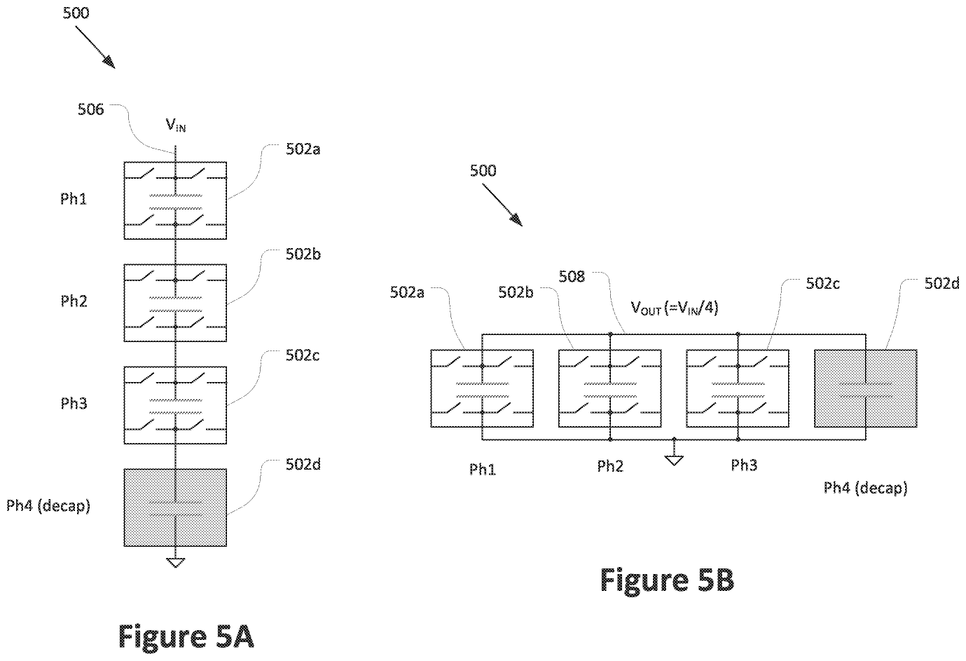

As discussed above, the embodiments herein may be used with voltage converters that include more than two phases. One or more of the phases may be in the decoupling mode during startup of the voltage converter to provide a decoupling capacitor. For example, FIGS. 5A and 5B illustrate a voltage converter 500 with four phases 502a-d. In some embodiments, the phases 502a-d may have a similar configuration to the phases 202 and 204 of voltage converter 200. As shown in FIG. 5A, the phase 502d of the voltage converter 500 may be in the decoupling mode during startup of the voltage converter 500 to act as a decoupling capacitor. The phases 502a-c may be in the switching mode to generate an output voltage at output terminal 508 based on an input voltage at input terminal 506. The phase 502d may transition from the decoupling mode to the switching mode for normal operation of the voltage converter 500 (e.g., as shown in FIG. 5B).

In some embodiments, the voltage converter 500 may be a 4-to-1 voltage converter. Accordingly, the output voltage may be about ¼ of the input voltage. Other conversion ratios may be used in accordance with various embodiments.

In some embodiments, the number of phases that are configured as decoupling capacitors during startup may be based on the conversion ratio. For example, for a conversion ratio of X:1, 1/X of the phases may be configured as decoupling capacitors during startup.

The embodiments herein may additionally or alternatively be used for other types of multi-phase switched capacitor converters, such as switched capacitor converters that use PFM, PWM, and/or another suitable control scheme. Furthermore, the embodiments may be used with switched capacitor converters that use phase shedding, in which one or more phases are inactivated, e.g., based on the load at the output (such as when the power draw is low). The phases that are inactivated may be converted to decoupling capacitors. The decoupling capacitors may reduce output ripple for the voltage converter.

Furthermore, in some embodiments, one or more phases may be configured to provide a decoupling capacitor at an input of the voltage converter, and/or at another circuitry node as needed.

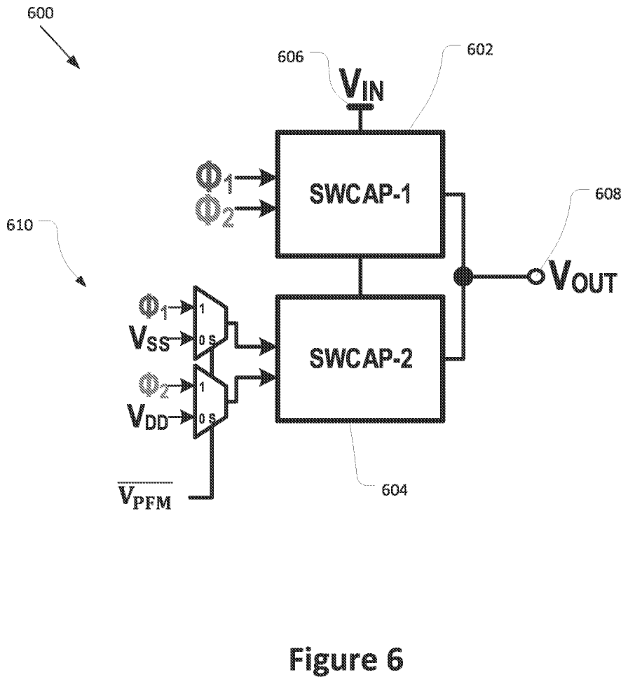

FIG. 6 illustrates a voltage converter 600 that uses PFM control, in accordance with various embodiments. The voltage converter 600 includes a first phase 602 and a second phase 604 coupled between an input terminal 606 and an output terminal 608 (e.g., in parallel with one another). With PFM control, the first phase 602 and second phase 604 may be switched on and off with a PFM signal in which the frequency is modified to control the operation of the voltage converter 600. For example, the pulse duration of the PFM signal may remain constant and the time between pulses may be adjusted. The PFM control may enable higher efficiency at low load levels compared with PWM and/or other techniques.

The voltage converter 600 may further include a control circuitry 610 to place the second phase 604 in the decoupling mode or the switching mode. The control circuitry 610 may select the operating mode based on a mode control signal V_{PFM}.

In some embodiments, the voltage converter 600 may utilize phase shedding, e.g., based on load conditions. Accordingly, the second phase 604 may be selectively inactivated and the first phase 606 may continue to operate in the switching mode (e.g., using PFM operation). When the second phase 604 is inactivated, it may operate in the decoupling mode to provide a decoupling capacitance. The decoupling capacitance may reduce the output ripple of the voltage converter 600.

These techniques may be extended to voltage converters with more than two phases. For example, all or a subset of phases that are inactive may be used as decoupling capacitors.

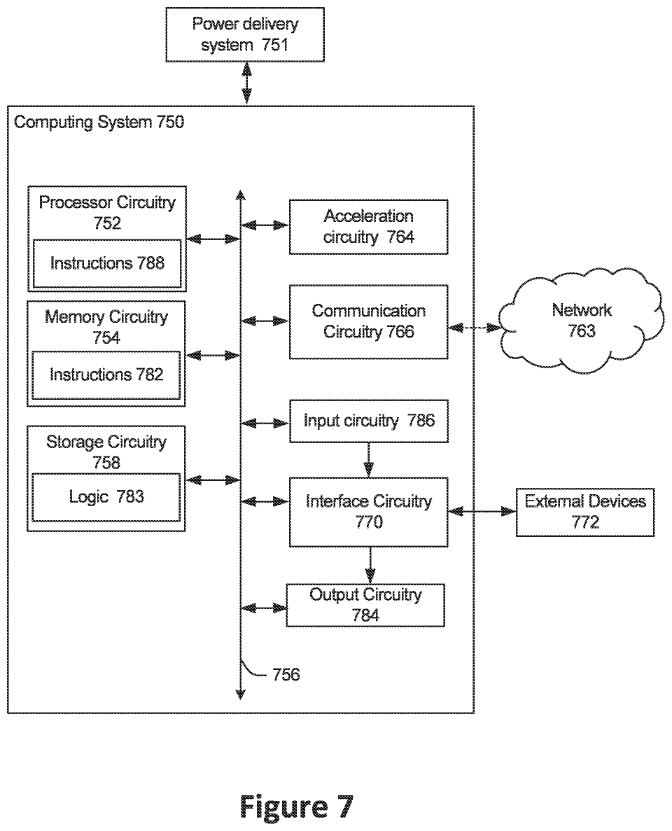

FIG. 7 illustrates an example of components that may be present in a computing system 750 for implementing the apparatuses, systems, and methods described herein. For example, the voltage converter and/or associated circuitry described herein may be included in one or more of power delivery subsystem 751, processor circuitry 752, memory circuitry 754, storage circuitry 758, acceleration circuitry 764, communication circuitry 766, input circuitry 786, interface circuitry 770, and/or output circuitry 784 of computing system 750.

The computing system 750 may be powered by a power delivery subsystem 751 and include any combinations of the hardware or logical components referenced herein. The components may be implemented as ICs, portions thereof, discrete electronic devices, or other modules, instruction sets, programmable logic or algorithms, hardware, hardware accelerators, software, firmware, or a combination thereof adapted in the computing system 750, or as components otherwise incorporated within a chassis of a larger system. For one embodiment, at least one processor 752 may be packaged together with computational logic 782 and configured to practice aspects of various example embodiments described herein to form a System in Package (SiP) or a System on Chip (SoC).

The system 750 includes processor circuitry in the form of one or more processors 752. The processor circuitry 752 includes circuitry such as, but not limited to one or more processor cores and one or more of cache memory, low drop-out voltage regulators (LDOs), interrupt controllers, serial interfaces such as SPI, I2C or universal programmable serial interface circuit, real time clock (RTC), timer-counters including interval and watchdog timers, general purpose I/O, memory card controllers such as secure digital/multi-media card (SD/MMC) or similar, interfaces, mobile industry processor interface (MIPI) interfaces and Joint Test Access Group (JTAG) test access ports. In some implementations, the processor circuitry 752 may include one or more hardware accelerators (e.g., same or similar to acceleration circuitry 764), which may be microprocessors, programmable processing devices (e.g., FPGA, ASIC, etc.), or the like. The one or more accelerators may include, for example, computer vision and/or deep learning accelerators. In some implementations, the processor circuitry 752 may include on-chip memory circuitry, which may include any suitable volatile and/or non-volatile memory, such as DRAM, SRAM, EPROM, EEPROM, Flash memory, solid-state memory, and/or any other type of memory device technology, such as those discussed herein

The processor circuitry 752 may include, for example, one or more processor cores (CPUs), application processors, GPUs, RISC processors, Acorn RISC Machine (ARM) processors, CISC processors, one or more DSPs, one or more FPGAs, one or more PLDs, one or more ASICs, one or more baseband processors, one or more radio-frequency integrated circuits (RFIC), one or more microprocessors or controllers, a multi-core processor, a multithreaded processor, an ultra-low voltage processor, an embedded processor, or any other known processing elements, or any suitable combination thereof. The processors (or cores) 752 may be coupled with or may include memory/storage and may be configured to execute instructions stored in the memory/storage to enable various applications or operating systems to run on the platform 750. The processors (or cores) 752 is configured to operate application software to provide a specific service to a user of the platform 750. In some embodiments, the processor(s) 752 may be a special-purpose processor(s)/controller(s) configured (or configurable) to operate according to the various embodiments herein.

As examples, the processor(s) 752 may include an Intel® Architecture Core™ based processor such as an i3, an i5, an i7, an i9 based processor; an Intel® microcontroller-based processor such as a Quark™, an Atom™, or other MCU-based processor; Pentium® processor(s), Xeon® processor(s), or another such processor available from Intel® Corporation, Santa Clara, California. However, any number other processors may be used, such as one or more of Advanced Micro Devices (AMD) Zen® Architecture such as Ryzen® or EPYC® processor(s), Accelerated Processing Units (APUs), MxGPUs, Epyc® processor(s), or the like; A5-A12 and/or S1-S4 processor(s) from Apple® Inc., Snapdragon™ or Centrig™ processor(s) from Qualcomm® Technologies, Inc., Texas Instruments, Inc.® Open Multimedia Applications Platform (OMAP)™ processor(s); a MIPS-based design from MIPS Technologies, Inc. such as MIPS Warrior M-class, Warrior I-class, and Warrior P-class processors; an ARM-based design licensed from ARM Holdings, Ltd., such as the ARM Cortex-A, Cortex-R, and Cortex-M family of processors; the ThunderX2® provided by Cavium™, Inc.; or the like. In some implementations, the processor(s) 752 may be a part of a system on a chip (SoC), System-in-Package (SiP), a multi-chip package (MCP), and/or the like, in which the processor(s) 752 and other components are formed into a single integrated circuit, or a single package, such as the Edison™ or Galileo™ SoC boards from Intel® Corporation. Other examples of the processor(s) 752 are mentioned elsewhere in the present disclosure.

The system 750 may include or be coupled to acceleration circuitry 764, which may be embodied by one or more AI/ML accelerators, a neural compute stick, neuromorphic hardware, an FPGA, an arrangement of GPUs, one or more SoCs (including programmable SoCs), one or more CPUs, one or more digital signal processors, dedicated ASICs (including programmable ASICs), PLDs such as complex (CPLDs) or high complexity PLDs (HCPLDs), and/or other forms of specialized processors or circuitry designed to accomplish one or more specialized tasks. These tasks may include AI/ML processing (e.g., including training, inferencing, and classification operations), visual data processing, network data processing, object detection, rule analysis, or the like. In FPGA-based implementations, the acceleration circuitry 764 may comprise logic blocks or logic fabric and other interconnected resources that may be programmed (configured) to perform various functions, such as the procedures, methods, functions, etc. of the various embodiments discussed herein. In such implementations, the acceleration circuitry 764 may also include memory cells (e.g., EPROM, EEPROM, flash memory, static memory (e.g., SRAM, anti-fuses, etc.) used to store logic blocks, logic fabric, data, etc. in LUTs and the like.

In some implementations, the processor circuitry 752 and/or acceleration circuitry 764 may include hardware elements specifically tailored for machine learning and/or artificial intelligence (AI) functionality. In these implementations, the processor circuitry 752 and/or acceleration circuitry 764 may be, or may include, an AI engine chip that can run many different kinds of AI instruction sets once loaded with the appropriate weightings and training code. Additionally or alternatively, the processor circuitry 752 and/or acceleration circuitry 764 may be, or may include, AI accelerator(s), which may be one or more of the aforementioned hardware accelerators designed for hardware acceleration of AI applications. As examples, these processor(s) or accelerators may be a cluster of artificial intelligence (AI) GPUs, tensor processing units (TPUs) developed by Google® Inc., Real AI Processors (RAPs™) provided by AlphaICs®, Nervana™ Neural Network Processors (NNPs) provided by Intel® Corp., Intel® Movidius™ Myriad™ X Vision Processing Unit (VPU), NVIDIA® PX™ based GPUs, the NM500 chip provided by General Vision®, Hardware 3 provided by Tesla®, Inc., an Epiphany™ based processor provided by Adapteva®, or the like. In some embodiments, the processor circuitry 752 and/or acceleration circuitry 764 and/or hardware accelerator circuitry may be implemented as AI accelerating co-processor(s), such as the Hexagon DSP provided by Qualcomm®, the PowerVR 2NX Neural Net Accelerator (NNA) provided by Imagination Technologies Limited®, the Neural Engine core within the Apple® A11 or A12 Bionic SoC, the Neural Processing Unit (NPU) within the HiSilicon Kirin 970 provided by Huawei®, and/or the like. In some hardware-based implementations, individual subsystems of system 750 may be operated by the respective AI accelerating co-processor(s), AI GPUs, TPUs, or hardware accelerators (e.g., FPGAs, ASICs, DSPs, SoCs, etc.), etc., that are configured with appropriate logic blocks, bit stream(s), etc. to perform their respective functions.

The system 750 also includes system memory 754. Any number of memory devices may be used to provide for a given amount of system memory. As examples, the memory 754 may be, or include, volatile memory such as random access memory (RAM), static RAM (SRAM), dynamic RAM (DRAM), synchronous DRAM (SDRAM), RAMBUS® Dynamic Random Access Memory (RDRAM®), and/or any other desired type of volatile memory device. Additionally or alternatively, the memory 754 may be, or include, non-volatile memory such as read-only memory (ROM), erasable programmable ROM (EPROM), electrically erasable programmable (EEPROM), flash memory, non-volatile RAM, ferroelectric RAM, phase-change memory (PCM), flash memory, and/or any other desired type of non-volatile memory device. Access to the memory 754 is controlled by a memory controller. The individual memory devices may be of any number of different package types such as single die package (SDP), dual die package (DDP) or quad die package (Q17P). Any number of other memory implementations may be used, such as dual inline memory modules (DIMMs) of different varieties including but not limited to microDIMMs or MiniDIMMs.

Storage circuitry 758 provides persistent storage of information such as data, applications, operating systems and so forth. In an example, the storage 758 may be implemented via a solid-state disk drive (SSDD) and/or high-speed electrically erasable memory (commonly referred to as “flash memory”). Other devices that may be used for the storage 758 include flash memory cards, such as SD cards, microSD cards, XD picture cards, and the like, and USB flash drives. In an example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, phase change RAM (PRAM), resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a Domain Wall (DW) and Spin Orbit Transfer (SOT) based device, a thyristor based memory device, a hard disk drive (HDD), micro HDD, of a combination thereof, and/or any other memory. The memory circuitry 754 and/or storage circuitry 758 may also incorporate three-dimensional (3D) cross-point (XPOINT) memories from Intel® and Micron®.

The memory circuitry 754 and/or storage circuitry 758 is/are configured to store computational logic 783 in the form of software, firmware, microcode, or hardware-level instructions to implement the techniques described herein. The computational logic 783 may be employed to store working copies and/or permanent copies of programming instructions, or data to create the programming instructions, for the operation of various components of system 750 (e.g., drivers, libraries, application programming interfaces (APIs), etc.), an operating system of system 750, one or more applications, and/or for carrying out the embodiments discussed herein. The computational logic 783 may be stored or loaded into memory circuitry 754 as instructions 782, or data to create the instructions 782, which are then accessed for execution by the processor circuitry 752 to carry out the functions described herein. The processor circuitry 752 and/or the acceleration circuitry 764 accesses the memory circuitry 754 and/or the storage circuitry 758 over the interconnect (IX) 756. The instructions 782 direct the processor circuitry 752 to perform a specific sequence or flow of actions, for example, as described with respect to flowchart(s) and block diagram(s) of operations and functionality depicted previously. The various elements may be implemented by assembler instructions supported by processor circuitry 752 or high-level languages that may be compiled into instructions 788, or data to create the instructions 788, to be executed by the processor circuitry 752. The permanent copy of the programming instructions may be placed into persistent storage devices of storage circuitry 758 in the factory or in the field through, for example, a distribution medium (not shown), through a communication interface (e.g., from a distribution server (not shown)), over-the-air (OTA), or any combination thereof.

The IX 756 couples the processor 752 to communication circuitry 766 for communications with other devices, such as a remote server (not shown) and the like. The communication circuitry 766 is a hardware element, or collection of hardware elements, used to communicate over one or more networks 763 and/or with other devices. In one example, communication circuitry 766 is, or includes, transceiver circuitry configured to enable wireless communications using any number of frequencies and protocols such as, for example, the Institute of Electrical and Electronics Engineers (IEEE) 802.11 (and/or variants thereof), IEEE 802.23.4, Bluetooth® and/or Bluetooth® low energy (BLE), ZigBee®, LoRaWAN™ (Long Range Wide Area Network), a cellular protocol such as 3GPP LTE and/or Fifth Generation (5G)/New Radio (NR), and/or the like. Additionally or alternatively, communication circuitry 766 is, or includes, one or more network interface controllers (NICs) to enable wired communication using, for example, an Ethernet connection, Controller Area Network (CAN), Local Interconnect Network (LIN), DeviceNet, ControlNet, Data Highway+, or PROFINET, among many others.

The IX 756 also couples the processor 752 to interface circuitry 770 that is used to connect system 750 with one or more external devices 772. The external devices 772 may include, for example, sensors, actuators, positioning circuitry (e.g., global navigation satellite system (GNSS)/Global Positioning System (GPS) circuitry), client devices, servers, network appliances (e.g., switches, hubs, routers, etc.), integrated photonics devices (e.g., optical neural network (ONN) integrated circuit (IC) and/or the like), and/or other like devices.

In some optional examples, various input/output (I/O) devices may be present within or connected to, the system 750, which are referred to as input circuitry 786 and output circuitry 784. The input circuitry 786 and output circuitry 784 include one or more user interfaces designed to enable user interaction with the platform 750 and/or peripheral component interfaces designed to enable peripheral component interaction with the platform 750. Input circuitry 786 may include any physical or virtual means for accepting an input including, inter alia, one or more physical or virtual buttons (e.g., a reset button), a physical keyboard, keypad, mouse, touchpad, touchscreen, microphones, scanner, headset, and/or the like. The output circuitry 784 may be included to show information or otherwise convey information, such as sensor readings, actuator position(s), or other like information. Data and/or graphics may be displayed on one or more user interface components of the output circuitry 784. Output circuitry 784 may include any number and/or combinations of audio or visual display, including, inter alia, one or more simple visual outputs/indicators (e.g., binary status indicators (e.g., light emitting diodes (LEDs)) and multi-character visual outputs, or more complex outputs such as display devices or touchscreens (e.g., Liquid Crystal Displays (LCD), LED displays, quantum dot displays, projectors, etc.), with the output of characters, graphics, multimedia objects, and the like being generated or produced from the operation of the platform 750. The output circuitry 784 may also include speakers and/or other audio emitting devices, printer(s), and/or the like. Additionally or alternatively, sensor(s) may be used as the input circuitry 784 (e.g., an image capture device, motion capture device, or the like) and one or more actuators may be used as the output device circuitry 784 (e.g., an actuator to provide haptic feedback or the like). Peripheral component interfaces may include, but are not limited to, a non-volatile memory port, a USB port, an audio jack, a power supply interface, etc. In some embodiments, a display or console hardware, in the context of the present system, may be used to provide output and receive input of an edge computing system; to manage components or services of an edge computing system; identify a state of an edge computing component or service; or to conduct any other number of management or administration functions or service use cases.

The components of the system 750 may communicate over the IX 756. The IX 756 may include any number of technologies, including ISA, extended ISA, I2C, SPI, point-to-point interfaces, power management bus (PMBus), PCI, PCIe, PCIx, Intel® UPI, Intel® Accelerator Link, Intel® CXL, CAPI, OpenCAPI, Intel® QPI, UPI, Intel® OPA IX, RapidIO™ system IXs, CCIX, Gen-Z Consortium IXs, a HyperTransport interconnect, NVLink provided by NVIDIA®, a Time-Trigger Protocol (TTP) system, a FlexRay system, PROFIBUS, and/or any number of other IX technologies. The IX 756 may be a proprietary bus, for example, used in a SoC based system.

The number, capability, and/or capacity of the elements of system 750 may vary, depending on whether computing system 750 is used as a stationary computing device (e.g., a server computer in a data center, a workstation, a desktop computer, etc.) or a mobile computing device (e.g., a smartphone, tablet computing device, laptop computer, game console, IoT device, etc.). In various implementations, the computing device system 750 may comprise one or more components of a data center, a desktop computer, a workstation, a laptop, a smartphone, a tablet, a digital camera, a smart appliance, a smart home hub, a network appliance, and/or any other device/system that processes data.

The techniques described herein can be performed partially or wholly by software or other instructions provided in a machine-readable storage medium (e.g., memory). The software is stored as processor-executable instructions (e.g., instructions to implement any other processes discussed herein). Instructions associated with the flowchart (and/or various embodiments) and executed to implement embodiments of the disclosed subject matter may be implemented as part of an operating system or a specific application, component, program, object, module, routine, or other sequence of instructions or organization of sequences of instructions.

The storage medium can be a tangible machine readable medium such as read only memory (ROM), random access memory (RAM), flash memory devices, floppy and other removable disks, magnetic storage media, optical storage media (e.g., Compact Disk Read-Only Memory (CD ROMS), Digital Versatile Disks (DVDs)), among others.

The storage medium may be included, e.g., in a communication device, a computing device, a network device, a personal digital assistant, a manufacturing tool, a mobile communication device, a cellular phone, a notebook computer, a tablet, a game console, a set top box, an embedded system, a TV (television), or a personal desktop computer.

### Examples

Some non-limiting examples of various embodiments are provided below.

Example 1 is a circuit comprising: a switched capacitor voltage converter that includes a plurality of phases coupled between an input terminal and an output terminal, wherein the plurality of phases each include a capacitor and switches, and wherein the plurality of phases include: a first phase to operate in a switching mode to generate an output voltage at the output terminal based on an input voltage at the input terminal; and a second phase that is selectively operable in the switching mode or in a decoupling mode, wherein, when the second phase is in the decoupling mode, the capacitor of the second phase is coupled between the output terminal and ground. The circuit further comprises a control circuitry coupled to the second phase, the control circuitry to operate the second phase in the decoupling mode while the first phase is in the switching mode, and to operate the second phase in the switching mode while the first phase is in the switching mode.

Example 2 is the circuit of example 1, wherein the control circuitry is to transition the second phase from the decoupling mode to the switching mode based on a voltage across the capacitor of the first phase.

Example 3 is the circuit of example 1 or example 2, wherein the control circuitry is to operate the second phase in the decoupling mode during startup of the switched capacitor voltage converter.

Example 4 is the circuit of any of examples 1-3, wherein the output voltage is less than the input voltage.

Example 5 is the circuit of any of examples 1-4, wherein the plurality of phases include more than two phases, and wherein the first phase is part of a subset of two or more of the phases that operate in the switching mode while the second phase is in the decoupling mode.

Example 6 is the circuit of example 5, wherein the subset is a first subset, and wherein the second phase is part of a second subset of two or more of the phases that are selectively operable in the switching mode or the decoupling mode.

Example 7 is the circuit of any of examples 1-6, wherein the switches of the respective phases include: a first switch coupled between the input terminal and a first terminal of the capacitor; a second switch coupled between the output terminal and a second terminal of the capacitor; a third switch coupled between the output terminal and the first terminal of the capacitor; and a fourth switch coupled between the second terminal of the capacitor and a ground terminal.

Example 8 is the circuit of example 7, wherein, in the switching mode, the first and second switches are responsive to a first control signal and the third and fourth switches are responsive to a second control signal, and wherein, in the decoupling mode, the control circuitry is to maintain the first and second switches in an open state and the third and fourth switches in a closed state.

Example 9 is the circuit of any of examples 1-8, wherein, in the switching mode, the first and second phases are to generate the output voltage using pulse frequency modulation or pulse width modulation.

Example 10 is a switched capacitor voltage converter comprising: a first phase coupled between an input and an output of the switched capacitor voltage converter, wherein the first phase includes a first capacitor and a first set of switches, and wherein the first phase is to operate in a switching mode in which the first set of switches open and close to generate an output voltage at the output based on an input voltage at the input; a second phase coupled in parallel with the first phase, wherein the second phase includes a second capacitor and a second set of switches, wherein the second phase is to operate in a decoupling mode in which the second capacitor is maintained as coupled between the output and a ground terminal, and wherein the second phase is further to transition from the decoupling mode to the switching mode.

Example 11 is the switched capacitor voltage converter of example 10, wherein the second phase is to operate in the decoupling mode during startup of the switched capacitor voltage converter.

Example 12 is the switched capacitor voltage converter of example 10 or 11, wherein the second phase is to transition from the decoupling mode to the switching mode based on a voltage across the first capacitor.

Example 13 is the switched capacitor voltage converter of example 11 or 12, wherein the first phase is to operate in the switching mode during startup of the switched capacitor voltage converter, and wherein the first phase is to remain in the switching mode when the second phase is in the switching mode.

Example 14 is the switched capacitor voltage converter of any of examples 10-13, wherein the second set of switches includes: a first switch coupled between the input of the switched capacitor voltage converter and a first terminal of the second capacitor; a second switch coupled between the output of the switched capacitor voltage converter and a second terminal of the second capacitor; a third switch coupled between the output of the switched capacitor voltage converter and the first terminal of the second capacitor; and a fourth switch coupled between the second terminal of the second capacitor and a ground terminal.

Example 15 is the switched capacitor voltage converter of example 14, wherein: when the second phase is in the switching mode, the first and second switches are responsive to a first control signal and the third and fourth switches are responsive to a second control signal; and when the second phase is in the decoupling mode, the first and second switches are maintained in an open state and the third and fourth switches are maintained in a closed state.

Example 16 is an integrated circuit comprising: a power supply interface to receive a first power supply; a circuit block to receive a second power supply that is less than the first power supply; and a power conversion circuit to generate the second power supply based on the first power supply, wherein the power conversion circuit includes: a voltage converter that includes an input terminal to receive an input voltage that corresponds to the first power supply, and to generate an output voltage, at an output terminal, that corresponds to the second power supply, wherein the voltage converter includes a plurality of phases coupled between the input terminal and the output terminal, and wherein the plurality of phases include: a first phase that includes a first capacitor and a first set of switches, wherein the first phase is to operate in a switching mode in which the first set of switches alternately switch the first capacitor between a first state, in which the first capacitor is coupled between the input terminal and the output terminal, and a second state, in which the first capacitor is coupled between the output terminal and a ground terminal; and a second phase that includes a second capacitor and a second set of switches, wherein the second phase is selectively operable in the switching mode or in a decoupling mode, and wherein the second set of switches maintain the second capacitor in the second state while the second phase is in the decoupling mode.

Example 17 is the integrated circuit of example 16, wherein, during startup of the voltage converter, the first phase is to operate in the switching mode and the second phase is to operate in the decoupling mode.

Example 18 is the integrated circuit of example 16 or 17, wherein the second phase is to transition from the decoupling mode to the switching mode based on a voltage across the first capacitor.

Example 19 is the integrated circuit of any of examples 16-18, wherein the second set of switches includes: a first switch coupled between the input of the voltage converter and a first terminal of the second capacitor; a second switch coupled between the output of the voltage converter and a second terminal of the second capacitor; a third switch coupled between the output of the voltage converter and the first terminal of the second capacitor; and a fourth switch coupled between the second terminal of the second capacitor and a ground terminal.

Example 20 is the integrated circuit of example 19, wherein: when the second phase is in the switching mode, the first and second switches are responsive to a first control signal and the third and fourth switches are responsive to a second control signal; and when the second phase is in the decoupling mode, the first and second switches are maintained in an open state and the third and fourth switches are maintained in a closed state.

Example 21 is a method comprising: controlling a first phase of a switched capacitor voltage converter to operate in a switching mode to generate an output voltage at an output terminal based on an input voltage at an input terminal; controlling a second phase of the switched capacitor voltage converter to operate in a decoupling mode while the first phase is in a switching mode, wherein, in the decoupling mode, a capacitor of the second phase is coupled between the output terminal and ground; and controlling the second phase to transition from the decoupling mode to the switching mode while the first phase remains in the switching mode.

Example 22 is the method of example 21, wherein the second phase is transitioned from the decoupling mode to the switching mode based on a voltage across a capacitor of the first phase.

Example 23 is the method of example 21 or example 22, wherein the second phase is in the decoupling mode during startup of the switched capacitor voltage converter.

Example 24 is the method of any of examples 21-23, wherein the output voltage is less than the input voltage.

Example 25 is the method of any of examples 21-24, wherein the switched capacitor voltage converter includes more than two phases, and wherein the first phase is part of a subset of two or more of the phases that operate in the switching mode while the second phase is in the decoupling mode.

Example 26 is the method of example 25, wherein the subset is a first subset, and wherein the second phase is part of a second subset of two or more of the phases that are selectively operable in the switching mode or the decoupling mode.

Example 27 is one or more non-transitory computer-readable media, that when executed by one or more processors of a device, configure the device to perform the method of any of examples 21-26.

Example 28 is a computer system that includes the circuit of any of examples 1-9, the switched capacitor voltage converter of any of examples 10-15, or the integrated circuit of any of examples 16-20, wherein the computer system further includes one or more of: a power supply to provide the input voltage, a memory, a network interface, or a display.

In the preceding detailed description, reference is made to the accompanying drawings that form a part hereof wherein like numerals designate like parts throughout, and in which is shown by way of illustration embodiments that may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

The terms “substantially,” “close,” “approximately,” “near,” and “about,” generally refer to being within +/−10% of a target value. Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, the phrases “A and/or B” and “A or B” mean (A), (B), or (A and B). For the purposes of the present disclosure, the phrase “A, B, and/or C” means (A), (B), (C), (A and B), (A and C), (B and C), or (A, B, and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “circuitry” may refer to, be part of, or include an Application Specific Integrated Circuit (ASIC), an electronic circuit, a processor (shared, dedicated, or group), a combinational logic circuit, and/or other suitable hardware components that provide the described functionality. As used herein, “computer-implemented method” may refer to any method executed by one or more processors, a computer system having one or more processors, a mobile device such as a smartphone (which may include one or more processors), a tablet, a laptop computer, a set-top box, a gaming console, and so forth.

Although certain embodiments have been illustrated and described herein for purposes of description, this application is intended to cover any adaptations or variations of the embodiments discussed herein. Therefore, it is manifestly intended that embodiments described herein be limited only by the claims.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

What is claimed is:

1. A circuit comprising:
a switched capacitor voltage converter that includes a plurality of phases coupled between an input terminal and an output terminal, wherein the plurality of phases each include a capacitor and switches, and wherein the plurality of phases include:
a first phase to operate in a switching mode to generate an output voltage at the output terminal based on an input voltage at the input terminal; and
a second phase that is selectively operable in the switching mode or in a decoupling mode, wherein, when the second phase is in the decoupling mode, the capacitor of the second phase is coupled between the output terminal and ground; and
a control circuitry coupled to the second phase, the control circuitry to operate the second phase in the decoupling mode while the first phase is in the switching mode, and to operate the second phase in the switching mode while the first phase is in the switching mode.

2. The circuit of claim 1, wherein the control circuitry is to transition the second phase from the decoupling mode to the switching mode based on a voltage across the capacitor of the first phase.

3. The circuit of claim 1, wherein the control circuitry is to operate the second phase in the decoupling mode during startup of the switched capacitor voltage converter.

4. The circuit of claim 1, wherein the output voltage is less than the input voltage.

5. The circuit of claim 1, wherein the plurality of phases include more than two phases, and wherein the first phase is part of a subset of two or more of the phases that operate in the switching mode while the second phase is in the decoupling mode.

6. The circuit of claim 5, wherein the subset is a first subset, and wherein the second phase is part of a second subset of two or more of the phases that are selectively operable in the switching mode or the decoupling mode.

7. The circuit of claim 1, wherein the switches of the respective phases include:
a first switch coupled between the input terminal and a first terminal of the capacitor;
a second switch coupled between the output terminal and a second terminal of the capacitor;
a third switch coupled between the output terminal and the first terminal of the capacitor; and
a fourth switch coupled between the second terminal of the capacitor and a ground terminal.

8. The circuit of claim 7, wherein, in the switching mode, the first and second switches are responsive to a first control signal and the third and fourth switches are responsive to a second control signal, and wherein, in the decoupling mode, the control circuitry is to maintain the first and second switches in an open state and the third and fourth switches in a closed state.

9. The circuit of claim 1, wherein, in the switching mode, the first and second phases are to generate the output voltage using pulse frequency modulation or pulse width modulation.

10. A switched capacitor voltage converter comprising:
a first phase coupled between an input and an output of the switched capacitor voltage converter, wherein the first phase includes a first capacitor and a first set of switches, and wherein the first phase is to operate in a switching mode in which the first set of switches open and close to generate an output voltage at the output based on an input voltage at the input;
a second phase coupled in parallel with the first phase, wherein the second phase includes a second capacitor and a second set of switches, wherein the second phase is to operate in a decoupling mode in which the second capacitor is maintained as coupled between the output and a ground terminal, and wherein the second phase is further to transition from the decoupling mode to the switching mode.

11. The switched capacitor voltage converter of claim 10, wherein the second phase is to operate in the decoupling mode during startup of the switched capacitor voltage converter.

12. The switched capacitor voltage converter of claim 11, wherein the second phase is to transition from the decoupling mode to the switching mode based on a voltage across the first capacitor.

13. The switched capacitor voltage converter of claim 11, wherein the first phase is to operate in the switching mode during startup of the switched capacitor voltage converter, and wherein the first phase is to remain in the switching mode when the second phase is in the switching mode.

14. The switched capacitor voltage converter of claim 10, wherein the second set of switches includes:
a first switch coupled between the input of the switched capacitor voltage converter and a first terminal of the second capacitor;
a second switch coupled between the output of the switched capacitor voltage converter and a second terminal of the second capacitor;
a third switch coupled between the output of the switched capacitor voltage converter and the first terminal of the second capacitor; and
a fourth switch coupled between the second terminal of the second capacitor and a ground terminal.

15. The switched capacitor voltage converter of claim 14, wherein:
when the second phase is in the switching mode, the first and second switches are responsive to a first control signal and the third and fourth switches are responsive to a second control signal; and
when the second phase is in the decoupling mode, the first and second switches are maintained in an open state and the third and fourth switches are maintained in a closed state.

16. An integrated circuit comprising:
a power supply interface to receive a first power supply;
a circuit block to receive a second power supply that is less than the first power supply; and
a power conversion circuit to generate the second power supply based on the first power supply, wherein the power conversion circuit includes:
a voltage converter that includes an input terminal to receive an input voltage that corresponds to the first power supply, and to generate an output voltage, at an output terminal, that corresponds to the second power supply, wherein the voltage converter includes a plurality of phases coupled between the input terminal and the output terminal, and wherein the plurality of phases include:
a first phase that includes a first capacitor and a first set of switches, wherein the first phase is to operate in a switching mode in which the first set of switches alternately switch the first capacitor between a first state, in which the first capacitor is coupled between the input terminal and the output terminal, and a second state, in which the first capacitor is coupled between the output terminal and a ground terminal; and
a second phase that includes a second capacitor and a second set of switches, wherein the second phase is selectively operable in the switching mode or in a decoupling mode, and wherein the second set of switches maintain the second capacitor in the second state while the second phase is in the decoupling mode.

17. The integrated circuit of claim 16, wherein, during startup of the voltage converter, the first phase is to operate in the switching mode and the second phase is to operate in the decoupling mode.

18. The integrated circuit of claim 16, wherein the second phase is to transition from the decoupling mode to the switching mode based on a voltage across the first capacitor.

19. The integrated circuit of claim 16, wherein the second set of switches includes:
a first switch coupled between the input of the voltage converter and a first terminal of the second capacitor;
a second switch coupled between the output of the voltage converter and a second terminal of the second capacitor;
a third switch coupled between the output of the voltage converter and the first terminal of the second capacitor; and
a fourth switch coupled between the second terminal of the second capacitor and a ground terminal.

20. The integrated circuit of claim 19, wherein:
when the second phase is in the switching mode, the first and second switches are responsive to a first control signal and the third and fourth switches are responsive to a second control signal; and
when the second phase is in the decoupling mode, the first and second switches are maintained in an open state and the third and fourth switches are maintained in a closed state.
